(19) United States
(12) Patent Application Publication
(10) Pub. No.: US 2021/0231215 A1
(43) Pub. Date: Jul. 29, 2021

(54) Seal

(71) Applicant: KACO GmbH + Co. KG, Kirchardt (DE)

(72) Inventors: Roland Lenz, Untereisesheim (DE); Cornelius Fehrenbacher, Nordheim (DE)

(21) Appl. No.: 17/160,408

(22) Filed: Jan. 28, 2021

(30) Foreign Application Priority Data
Jan. 28, 2020 (DE) 10 2020 000 632.9

(51) Int. Cl. F16J 15/08

(52) U.S. Cl. CPC F16J 15/0818; F16J 15/0806

(57) ABSTRACT

The seal has a support body at which at least one sealing body is provided. The support body is electrically conductive at least in a region projecting past the at least one sealing body. The at least one sealing body seals against a penetrating medium while the support body shields against emission of electrical disturbance sources.

### BACKGROUND OF THE INVENTION

The invention concerns a seal with at least one support body at which at least one sealing body is provided.

With the introduction of electrification of road vehicles, new requirements for the seals are encountered with regard to the sealing action and shielding action, in particular in the field of the battery housings as well as enclosures for power electronics. Thus, the electronics must be protected from environmental influences and, conversely, the environment must be protected with respect to electromagnetic disturbance sources such as alternating fields or waves.

Known sealing configurations are comprised of foam rubber, cellular rubber or combinations of electrically conductive elastomeric shaped seals. Also, conductive adhesives are known which are used in electrical cabinets, enclosures, and the like.

In a vibration-loaded screw connection, these seals are unsuitable because, by means of the vibrations and/or also by micro movements of housing parts, the elasticity of the sealing material decreases or is even lost. In addition, there is the problem that such elastomeric seals can be removed only with difficulty when a housing must be opened, for example. Sometimes, adhering seal parts must be cleaned off the housing parts. Particularly frequently, it even happens that the housing part must be post-machined after removal.

In addition, conductive adhesives/liquid seals are not suitable for pressure applications.

Such seals require too much installation space as combined solutions and are not suitable for mass production. Also, such seals cannot be repaired easily or only with difficulty.

The invention has the object to configure the seal of the aforementioned kind such that it can fulfill the requirements, in particular in road vehicles of the automotive industry, with regard to costs, suitability for mass production, compact configuration, and installation space optimization.

### SUMMARY OF THE INVENTION

This object is solved for the seal of the aforementioned kind in accordance with the invention in that the support body is embodied electrically conductively at least in a region projecting past the sealing body.

With the seal according to the invention, it is possible to ensure not only a sealing action in regard to outer environmental influences but at the same time shield also the environment from electrical disturbance sources according to EMC. The seal according to the invention combines thus two functions, namely the sealing action and the shielding action. Therefore, separate components are not required for fulfilling these two functions. The support body of the seal serves, on the one hand, as fastening means of the sealing body and, on the other hand, due to its electrically conductive configuration, as a shielding element relative to electromagnetic disturbance sources in the region that is projecting past the sealing body.

The sealing body which is comprised of elastomeric material, preferably of silicone, can be used with respect to penetrating medium up to IP code 9K. The IP protection code 9K provides protection against very intensive water jet, for example, high pressure stream cleaners in case of vehicles. In particular, by means of the seal, the correspondingly sealed housing in a vehicle is sealed properly when driving through water. This is in particular important when a battery housing in which lithium batteries are located is sealed with the seal. Moreover, the sealing body of the seal according to the invention is characterized by a high change of climate stability and salt spray stability. Damaging contact corrosion can be avoided also by means of the seal.

The region of the support body which is projecting past the sealing body comes into electrically conductive contact with those components between which the seal is installed. The seal thus shields reliably the housing against emission of electrical disturbance sources.

In order to achieve a good electrically conductive connection between the components, the region of the support body which is projecting past the sealing body is deformable, advantageously elastically deformable. In the installed position, the projecting support body region, when it is elastically deformed, is resting with pretension against the two components between which the seal is clamped.

In principle, it can also be sufficient when the projecting region of the support body is plastically deformed.

Advantageously, the entire support body is comprised of electrically conductive material. This enables a simple and inexpensive manufacture of the support body.

In this context, it is particularly advantageous when the support body is formed of a metal sheet. It enables a simple and inexpensive manufacture of the support body. Thus, the support body can be separated in a simple way from the metal sheet by a punching method, a jet cutting method and the like, wherein the support body, depending on the location of use of the seal, can have various contour shapes.

In order to achieve a good electrically conductive connection between the components to be sealed, at least the region of the support body which is projecting past the sealing body is embodied as a shaped part. It can be designed such that it is elastically deformed between the components which are to be sealed relative to each other in such a way that it is contacting with a sufficiently high pretension force the sides of the components that are facing each other.

In a preferred embodiment as a shaped part, the projecting region of the support body can have a rib-shaped structure. Such a structure is beneficial when blocking layers such as oxide layers, which make difficult or even prevent an electrically conductive connection between the components and the support body, are located or can be formed at the sides of the components facing each other. In this case, such a blocking layer is penetrated by the ribs so that a proper contact between the support body and the components is ensured.

In this context, the ribs can taper to a point in an advantageous manner whereby the penetration of a blocking layer is significantly simplified.

There is further the possibility of arranging the region of the support body that is projecting past the sealing body so as to be displaced, transversely to the plane of the support body, in relation to that region in which the sealing body is provided (sealing body region). This support body region comprising the sealing body (sealing body region) is therefore positioned in a different plane than the projecting support body region. When the components are connected fixedly to each other with interposition of the seal, the displaced support body region is reliably elastically deformed due to this configuration of the support body so that the electrically conductive connection between the components is ensured through the support body.

The electrically conductive connection between the components can be improved in an advantageous embodiment in that the support body region that is projecting past the sealing body is embodied with a profiling transverse to the longitudinal direction of the support body.

Such a profiling can be formed by profile parts which are arranged sequentially in circumferential direction. They can immediately adjoin each other but can also have a distance from each other, respectively. These profile parts are reliably elastically deformed when joining the components whereby a good electrical contacting between the components and the support body results.

In a simple and cost-efficient embodiment, the profile parts of the support body are embodied as a corrugated structure.

According to another advantageous embodiment, the profiling which is provided at the projecting support body region extends in longitudinal direction of the support body. In cross section, it is advantageously of a corrugated shape wherein the corrugations are positioned one after another transverse to the longitudinal direction of the support body. Upon joining of the components, this profiling is elastically deformed and ensures good contacting.

It is further possible to provide the support body with at least one form fit means. With it, the positioning of the seal relative to the components can be achieved in a simple way. In addition, these form fit means can also be utilized for additional contacting with the components.

The form fit means can be, for example, elements extending transversely to the support body, preferably can be transversely projecting tabs.

A further possibility for improving contacting between the support body and the components resides advantageously in providing the projecting part of the support body with at least one projecting pin. Upon joining the components, the pin is compressed at high forces which contributes to good contacting.

A further improvement of the electrically conductive connection between the components and the support body can be achieved in that at least the projecting region of the support body is provided with an electrically conductive coating. The basic support body itself must then not be comprised of electrically conductive material, which may lead to reduced manufacturing costs.

In order to optimize the sealing action relative to external effects, it is advantageous to provide the sealing body with a profiling at least at one side of the support body. When joining the components that are to be sealed relative to each other, the profiling is elastically deformed whereby a proper sealing action results.

In order for the region of the support body that is projecting past the sealing body not to impair the function of the sealing body, it is advantageous when the thickness of the support body is smaller than the height of the sealing gap to be sealed between the components. With such a configuration, it is ensured in any case that the sealing body is elastically deformed by the components.

The subject matter of the application results not only from the subject matter of the individual claims but also from the specifications and features disclosed in the drawings and the description. They are claimed as important to the invention even if they are not subject matter of the claims inasmuch, as individually or in combination, they are novel relative to the prior art.

Further features of the invention result from the additional claims, the description, and the drawings.

### BRIEF DESCRIPTION OF THE DRAWINGS

The invention will be explained in more detail with the aid of some embodiments illustrated in the drawings.

FIG. 1 shows in perspective illustration a seal according to the invention.

FIG. 2 shows in perspective illustration a portion of a second embodiment of a seal according to the invention.

FIG. 2a shows in a section view a further embodiment of a support body of the seal according to the invention.

FIG. 3 shows in section view and enlarged a different configuration of a support body of the seal according to the invention.

FIG. 4 shows in section view and enlarged another configuration of a support body of the seal according to the invention.

FIG. 5 shows in section view and enlarged yet another configuration of a support body of the seal according to the invention.

FIG. 6 shows in perspective illustration a portion of a support body of the seal according to the invention.

FIG. 7 shows in enlarged illustration a section view through the support body according to FIG. 6.

FIG. 8 shows in perspective illustration a portion of a further embodiment of a support body of the seal according to the invention.

FIG. 9 shows in enlarged illustration a section view of the support body according to FIG. 8.

FIG. 10 shows in a section view a further embodiment of a support body of a seal according to the invention.

FIG. 11 shows in schematic illustration a portion of a seal according to the invention that is arranged between two components.

FIG. 12 shows an additional contact location in the support body of the seal according to the invention, in section view and enlarged.

FIG. 13 shows an additional contact location in the support body of the seal according to the invention, in section view and enlarged.

FIG. 14 shows in perspective illustration an embodiment of contact locations in the support body of the seal according to the invention.

FIG. 15 shows in perspective illustration an embodiment of contact locations in the support body of the seal according to the invention.

FIG. 16 shows in section view and enlarged an embodiment of a sealing body of the seal according to the invention.

FIG. 17 shows in section view and enlarged a further embodiment of a sealing body of the seal according to the invention.

FIG. 18 shows in section view and enlarged another embodiment of a sealing body of the seal according to the invention.

FIG. 19 shows in section view and enlarged yet another embodiment of a sealing body of the seal according to the invention.

FIG. 20 shows in section view and enlarged a further embodiment of a sealing body of the seal according to the invention.

FIG. 21 shows in section view and enlarged another embodiment of a sealing body of the seal according to the invention.

FIG. 22 shows in schematic illustration and in section a support body of the seal according to the invention with a further embodiment of the sealing body.

FIG. 22a shows a section view along the section line XXIIa-XXIIa in FIG. 22 in enlarged illustration.

FIG. 22b shows a section view along the section line XXIIb-XXIIb in FIG. 22 in enlarged illustration.

FIG. 23 shows in section view a support body of the seal according to the invention clamped between two components in a further embodiment.

FIG. 24 shows in schematic illustration and in section view a support body of the seal according to the invention clamped between two components.

FIG. 25 shows in perspective illustration a further embodiment of a seal according to the invention.

### DESCRIPTION OF PREFERRED EMBODIMENTS

The seal described in the following is embodied as a combination seal that can be used as a sealing and shielding element between components, preferably in the automotive sector. The seal is designed such that it can be used as shielding of electrical disturbance sources according to EMC (electromagnetic compatibility) and for sealing relative to penetrating media. In this context, the sealing effect is designed such that it satisfies the IP requirements of IP code 9K. The IP code 9K ensures that a protection against water is ensured in case of a high pressure/steam cleaning action, in particular for road vehicles.

The seal has a support body which serves as a carrier of an elastomeric sealing body and also as an electrically conductive shielding element. The support body combines in this manner advantageously both functions in a single component.

FIG. 1 shows in an exemplary fashion such a seal S that is configured as an elongate oval sealing ring. The illustrated configuration of the seal S is to be understood only as an example. Depending on the field of use, the seal S can have various contour shapes.

The seal S has a support body 1 which has the same contour shape as the entire seal. The support body 1 is embodied as a ring and comprises centrally an opening 2.

The support body 1 is provided at least at one side with a sealing body 3 which seals against penetration of dirt, moisture, and the like. The sealing body 3 is arranged in a sealing body region of the support body 1 and is not provided across the entire width of the support body 1; the support body 1 projects past the sealing body 3 at least inwardly. The support body 1 serves as an electrically conductive shielding element and is elastically deformed in the installation position of the seal S between components 4, 5 (FIG. 11) to be sealed relative to each other, which are, for example, housing parts; in the following, the components are also referred to as housing parts 4, 5.

The support body 1 is comprised of electrically conductive material. Advantageously, the support body 1 is produced of a metallic material that enables an inexpensive manufacture. As a metallic material, advantageously steel or aluminum can be used.

There is further the possibility of manufacturing the support body 1 of an electrically conductive plastic material. It is advantageously a thermoset resin that has a sufficient stability and can be deformed between the two housing parts 4, 5 that are to be sealed relative to each other.

It is possible to provide at least the projecting region of the support body 1 that is projecting past the sealing body 3 with an electrically conductive coating. Then the basic support body itself must not be comprised of an electrically conductive material. This can lead to reduced manufacturing costs of the seal.

The sealing body 3 is comprised advantageously of elastomeric material, preferably silicone. The sealing body 3 is attached in a suitable manner to the support body 1, for example, glued on, in case of appropriate material vulcanized thereto, and the like.

The support body 1 is shaped across its width and/or length such that it is elastically deformed upon compression between the two housing parts 4, 5 (FIG. 11). Then the electrically conductive support body 1 connects both housing parts 4, 5 electrically conductively to each other. The support body 1 is configured such that it connects electrically conductively the two housing parts 4, 5 to each other about its circumference.

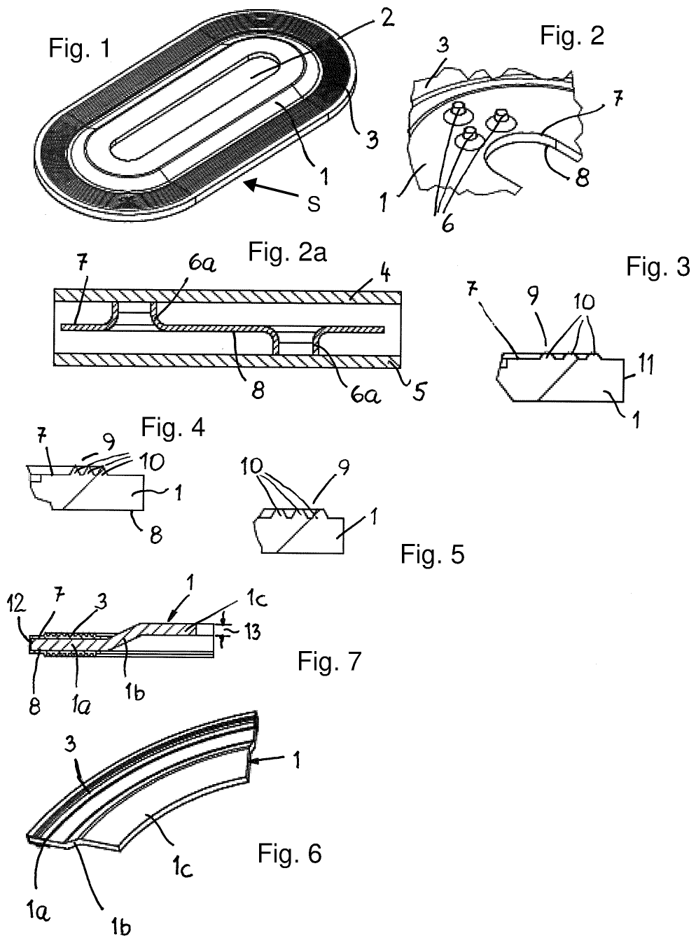

In order to improve the electrically conductive connection between the housing parts 4, 5, the support body 1, as illustrated in FIG. 2 in an exemplary fashion, can be provided with projecting pins 6 which are comprised of electrically conductive material and are arranged so as to be distributed about the circumference of the support body 1. The pins 6 can project past one side 7 but also past the oppositely positioned side 8 of the support body 1. Also, the support body 1 can be designed such that it comprises the projecting pins 6 at both outer sides 7, 8. They are connected electrically conductively to the support body 1 and have such a length that, in the installed position of the seal between the two housing parts 4, 5, they have electrically conductive contact with the latter. Upon compression of the seal between the two housing parts, 4, 5, the pins 6 are compressed so that a good contact between the pins 6 and the housing parts 4, 5 is ensured.

In place of the pins 6, as needed also additionally thereto, the support body 1 can be provided with necks 6a (FIG. 2a) in the region which is projecting past the sealing body 3. They project past one and/or the other outer side 7, 8 of the support body 1. The necks 6a are sleeve-shaped and can be produced in a known manner by means of a necking tool.

In the same manner as the pins 6, the necks 6a are compressed upon joining of the housing parts 4, 5 and a secure contacting action is achieved.

FIG. 3 shows the possibility of providing the support body 1 at least at one outer side 7 with a profiling 9. It is formed by elevations 10 extending about the circumference of the support body; they have a minimal distance from each other and are approximately of a semicircular shape in section view.

When the seal is clamped between the housing parts 4, 5, the annularly extending elevations 10 ensure that the oxide layers are penetrated at the contact side of the housing parts so that the electrically conductive connection between the housing parts 4, 5 is ensured via the support body 1 of the seal. Such oxide layers form particularly when the housing parts 4, 5 are comprised of aluminum.

In comparison to the thickness of the support body 1, the elevations 10 have only a minimal height. The elevations 10 are only so tall that they can penetrate possibly existing oxide layers at the contact regions to the housing parts 4, 5.

The support body 1 is advantageously comprised—this applies also to the other embodiments—of a metal sheet that enables a simple and inexpensive manufacture of the support body 1. The elevations 10 can be produced in this context by a simple punching process.

The elevations 10 each have the same height and each have the same distance from each other. Depending on the application situation, it is possible that the elevations 10 have a different height and/or different distance from each other.

The profiling 9 has a spacing from the rim 11 of the opening 2.

In the embodiment according to FIG. 4, the profiling 9 is of a sawtooth shape. The elevations 10 adjoin each other in this context, respectively, and are configured to taper to a point. With their pointed end face, possibly existing oxide layers in the contact regions to the housing parts 4, 5 can be reliably penetrated so that a proper electrically conductive connection between the housing parts 4, 5 is ensured via the support body 1.

In other respects, the profiling 9 is of the same configuration as in the preceding embodiment. The support body 1 can have the profiling not only at said one outer side 7 but also at the oppositely positioned outer side 8 of the support body 1. This is also possible in the embodiment according to FIG. 3 as well as in the embodiments that will be described in the following.

When the profilings 9 are provided at both outer sides 7, 8 of the support body 1, they can be embodied identical at both sides but also differently. This is possible without problems because the profilings 9, when the support body 1 is comprised of sheet metal, can be produced by a simple punching process.

When the support body 1 is comprised of an electrically conductive plastic material or is provided with an electrically conductive coating, the profilings 9 can be provided also at least at one of the two outer sides 7, 8 of the support body 1 in a simple manner.

The contact parts 6, 9 of the embodiments according to FIGS. 2 to 5 are provided in the region adjacent to the sealing body 3. The pins 6 or the profilings 9 are designed such that a sealing action between the two housing parts 4, 5 can be achieved by means of the sealing body 3 and that additionally also the electrically conductive contact between the two housing parts 4, 5 can be produced with the pins 6 or the necks 6a or the profilings 9.

In the embodiment according to FIGS. 6 and 7, the support body 1 is not provided with pins or profilings. The part of the support body 1 which is projecting inwardly past the sealing body 3 is of an angular configuration in cross section. In the outer region 1a, the support body 1 is embedded at both outer sides 7, 8 in the sealing body 3 (the sealing body region of the support body). The sealing body 3 extends also about the outer rim 12 of the support body 1. The outer support body part 1a that is embedded in the sealing body 3 (sealing body region) is planar and is connected by a conical center part 1b with an inner planar support body part 1c. Support body part 1c is positioned in the illustration according to FIGS. 6 and 7 in the region above the outer support body part 1a and above the part of the sealing body 3 which is present on the outer side 7.

The sealing body 3 can also extend up to the conical center part 1b but can also have a distance therefrom.

When such a seal is clamped between the two housing parts 4, 5 (FIG. 11), the inner support body part 1c is elastically deformed between the two housing parts 4, 5. The support body part 1c is compressed in this context to the sealing height until the sealing gap height between the housing parts 4, 5 is reached. Then the support body part 1c is contacting electrically conductively the two inner sides of the two housing parts 4, 5 which are facing each other. At the same time, the sealing body 3 is elastically deformed between the two housing parts 4, 5 to such an extent that a proper sealing action is ensured. In this way, about the circumference of the seal, the sealing action between the housing parts 4, 5 by means of the sealing body 3 and the electrically conductive connection of the housing parts 4, 5 by means of the support body 1 is achieved.

The inner support body 1c can comprise the pins 6 or profilings 9 as they are illustrated in an exemplary fashion in FIGS. 2 to 5. They ensure in the described manner a reliable electrically conductive connection between the housing parts 4, 5.

Upon elastic deformation of the one-piece support body 1, also the conical center part 1b is elastically deformed which ensures contacting of the two housing parts 4, 5 in connection with the inner support body part 1c.

As shown in FIG. 7, the transition from the center part 1b to the outer part 1a is designed such that the support body 1 can come into contact with the two housing parts 4, 5 at this transition location. The part of the sealing body 3 that is covering the outer side 8 has a distance from the transition region between the outer part 1a and the center part 1b.

As can be seen in FIG. 6, this transition region which is not covered by the sealing body 3 can have a sufficiently large width so that the support body 1 in the installed position can reliably electrically conductively connect the two housing parts 4, 5 to each other.

The thickness 13 of the support body 1 (FIG. 7) is smaller than the sealing gap height between the two housing parts 4, 5. Due to this action principle, the pretension force or clamping action can be respectively designed independent of the two functions of the seal advantageously either for the sealing action of the sealing body 3 or the electrically conductive connection by means of the support body 1.

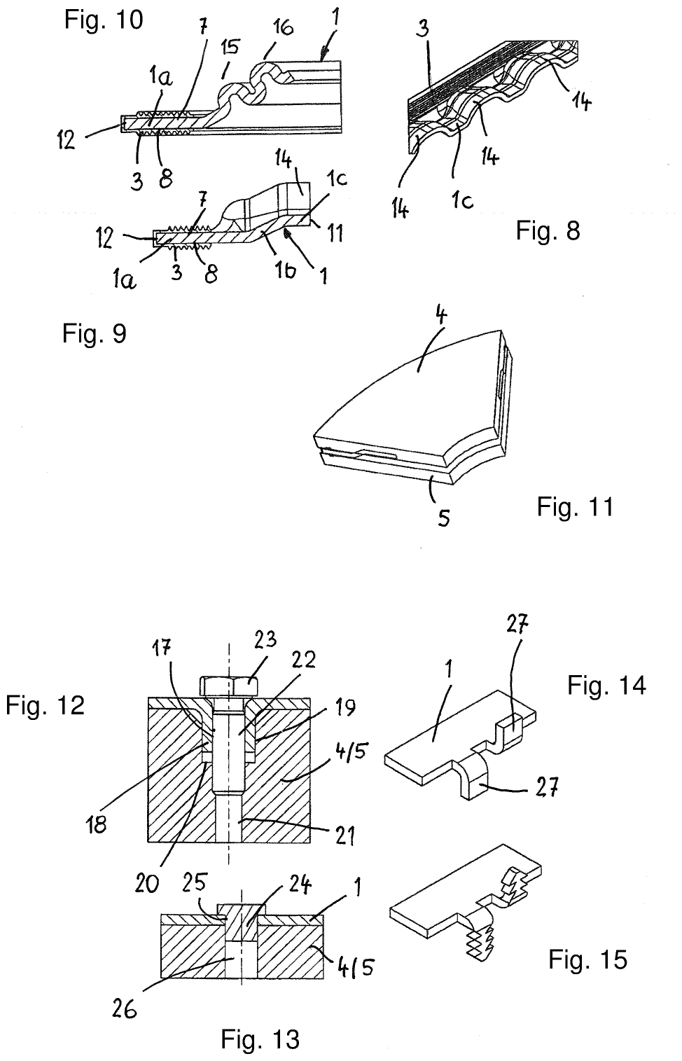

In the embodiment according to FIGS. 8 and 9, the outer support body part 1a of the support body 1 is covered in the described manner by the sealing body 3 at the two outer sides 7, 8 and at the outer rim 12, as has been explained in connection with FIGS. 6 and 7.

While in the preceding embodiment the conical center part 1b and the inner part 1c are configured straight in section, in the embodiment according to FIGS. 8 and 9 both parts are configured with a corrugated profiling in circumferential direction. The support body 1 has accordingly corrugations 14 extending in circumferential direction which extend from the circumferential rim 11 of the opening 2 of the seal to the outer support body part 1a. The corrugations 14 are sequentially positioned in circumferential direction of the support body 1 at a distance to each other.

The corrugations 14 are designed such that they can extend into the support body part 1a.

The corrugations 14, viewed in a section view extending in circumferential direction, can be embodied in a corrugated shape.

Since the corrugations 14 are projecting past the outer side 7 in the region of the support body part 1a, they are elastically deformed upon clamping between the housing parts 4, 5 so that a proper electrically conductive connection between the housing parts 4, 5 is achieved.

The sealing body 3 extends at the outer side 8 of the support body 1 or its outer support body part 1a only across a portion of its width, for example, only across half the width of the support body part 1a. This contributes to a good electrically conductive connection between the housing parts 4, 5 via the support body 1.

The corrugations 14 which are provided about the circumference of the support body parts 1b, 1c can be produced by a simple deformation process.

While in the afore described embodiment the deformation is provided in circumferential direction of the support body 1, FIG. 10 shows an example in which the profiling of the support body parts 1b, 1c can be provided also across the width of the support body 1. Both parts can be curved in an arc shape in section, respectively. In this way, across the width of the support body 1, an approximately meander-shaped cross-sectional course of the profilings 15, 16 of the two support body parts 1b and 1c results. The two profilings 15, 16 project past the outer side 7 of the support body part 1a which, in accordance with the preceding embodiment, is covered by the sealing body 3 which extends across the outer rim 12 to the outer side 8 of the support body part 1a. When such a seal is clamped between the two housing parts 4, 5, the profilings 15, 16 are elastically deformed to such an extent that the sealing body 3 in accordance with the preceding embodiments seal-tightly contacts the inner sides of the housing parts 4, 5 which are facing each other. Since the profilings 15, 16, which are elastically deformed in the installation position, are contacting with pretension the housing parts 4, 5, a safe electrically conductive connection between the housing parts 4, 5 via the support body 1 of the seal is provided.

The corrugated structure of the profilings 15, 16 extends in circumferential direction of the support body 1. In this way, across the circumference of the seal a good contacting of the support body 1 in relation to the housing parts 4, 5 is provided.

FIGS. 12 and 13 show the possibility of connecting the support body 1 with form fit with one or with both of the oppositely positioned housing parts 4, 5 that are to be sealed. The support body 1 is provided with at least one fastening opening 17 whose rim is deformed for forming a sleeve 18. The sleeve 18 is inserted into a corresponding plug-in opening 19 in the housing part 4, 5 having a threaded bore 21 that is provided at its bottom 20. The sleeve 18 serves as a centering means of the support body 1 and thus of the seal relative to the housing part 4, 5 and is contacting the side wall of the plug-in opening 19. A screw 22 is pushed through the sleeve 18 and is screwed into the threaded bore 21 of the housing part 4, 5. The screw 22 is positioned with its head 23 on the support body 1 and pushes the latter against the corresponding outer side of the housing part 4, 5.

In order to achieve a safe attachment of the support body 1 at the housing part 4, 5, the sleeve 18 has a distance from the bottom 20 of the plug-in opening 19 so that the support body 1 is pushed by means of the screw 22 fixedly against the housing part 4, 5.

Depending on the size of the seal and thus of the support body 1, a plurality of such fastening devices can be provided distributed about the circumference.

The fastening opening 17 is located in the inner support body part 1c. Instead of the screw 22, a set pin can be used also.

FIG. 13 shows the possibility of fastening the support body 1 by means of clinching (joining by shearing and upsetting) at least at one housing part 4, 5. The support body 1 has an opening 25 which receives a fastening body 24. The housing part 4, 5 is provided with an opening 26 into which the fastening body 24 is pressed.

As in the embodiment according to FIG. 12, the support body 1 can be connected by means of a plurality of fastening bodies 24 to the housing part 4, 5. The openings 25 are provided in the inner support body part 1c and arranged in distribution about the circumference, in case a plurality of fastening bodies 24 are used.

By means of the fastening bodies 24, the seal is fixed at the respective housing part 4, 5 and at the same time also positioned in the installation position relative to the housing parts 4, 5.

In the embodiment according to FIG. 14, the support body 1 is provided at the inner/outer rim with upwardly and downwardly bent tabs 27 having corresponding receptacles in the housing part 4, 5 correlated therewith. The tabs 27 are bent upwardly or downwardly relative to the support body 1 by 90°, respectively.

In the embodiment according to FIG. 15, the tabs 27 are provided at their longitudinal rims with a sawtooth profile 28 with which a reliable connection with the housing parts 4, 5 is possible.

With the embodiment of the support body 1 according to FIGS. 12 to 15, the seal is positioned relative to the housing parts 4, 5 in a simple manner in its position. At the same time, the form fit parts of the support body 1 provide additional contact locations which improve the electrically conductive connection between the support body 1 and the housing parts 4, 5.

The tabs 27 according to FIGS. 14 and 15 can also have any other suitable configuration in deviation from the illustrated embodiment in order to achieve a form-fit connection between the support body 1 and the housing parts 4, 5. The tabs 27 in this context can be designed such that they can be pressed into the housing parts 4, 5 upon screwing together the housing parts with interposition of the seal.

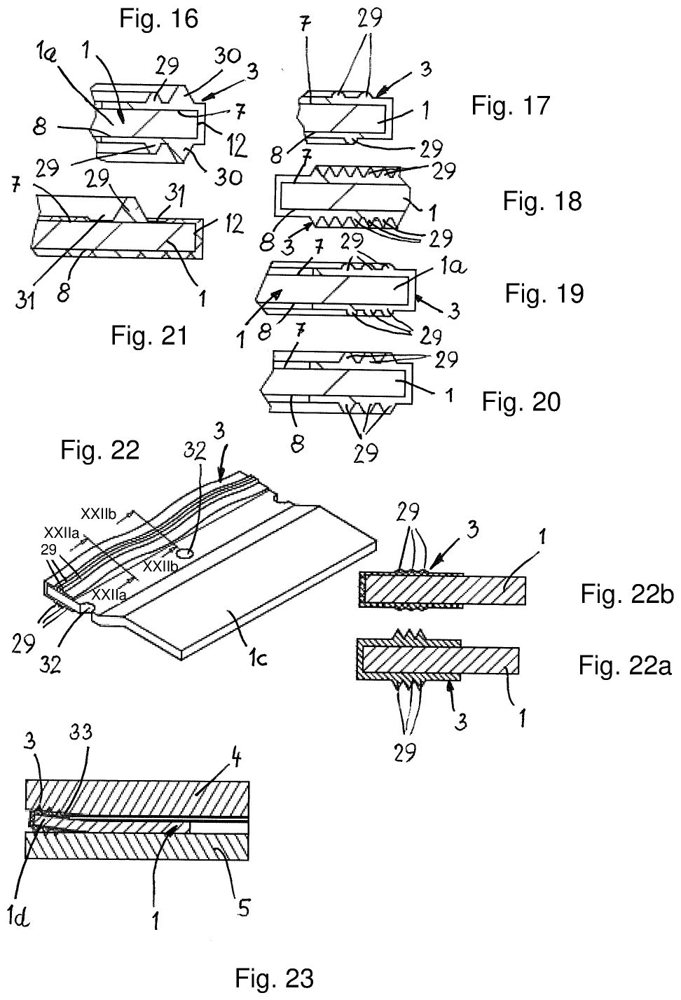

The sealing body 3 of the seal can have various shapes which will be explained in an exemplary fashion with the aid of FIGS. 16 to 21.

In the embodiment according to FIG. 16, the sealing body 3 is designed such that it covers the support body or its support body part 1a at its two outer sides 7, 8 as well as at the exterior rim 12. The sealing body 3 extends advantageously only across a portion (sealing body region) of the width of the support body part 1a as well as across its entire circumference. In this way, it is ensured that about the circumference of the seal the two housing parts 4, 5 are sealed reliably relative to each other.

Depending on the application situation, the outer rim 12 of the support body 1 can also be exposed, i.e., not covered by the sealing body 3.

The sealing body 3 is provided at both outer sides with annular projections 29, 30 which have different height and extend about the circumference of the seal. The projection 30 which is positioned adjacent to the outer rim 12 has a greater height than the projection 29 neighboring it.

The annular projections 29, 30 which are positioned at both sides of the support body 1 are of identical configuration, respectively.

When screwing together the housing parts 4, 5, it is ensured in any case that at least the higher annular projection 30 upon screwing together the housing parts 4, 5 is elastically deformed since the two annular projections 29, 30 have a different height. Advantageously, however also the other projection 29 is correspondingly elastically deformed. Since the sealing body 3 is comprised of an elastomeric material, a large sealing surface between the sealing body 3 and the housing parts 4, 5 is achieved due to the elastic deformation of the sealing body 3.

The sealing body according to FIG. 17 again has on one side of the support body 1 two annular projections 29 which, in contrast to the preceding embodiment, have however the same height.

At the oppositely positioned side of the support body 1, the sealing body 3 is provided with only one annular projection 29 which is of the same configuration as the projections 29 at the oppositely positioned side. The annular projection 29 at the outer side 8 of the support body 1 is located, viewed in plan view, centrally between the two annular projections 29 at the outer side 7 of the support body 1 that have a distance from each other.

In the embodiment according to FIG. 18, the support body 3 has the same structure at both outer sides 7, 8 of the support body 1 which is formed by a plurality of adjacently positioned projections 29 which, in contrast to the embodiments of FIGS. 16 and 17, adjoin each other. Corresponding to the embodiments according to FIGS. 16 and 17, the projections taper in the direction toward their ends. Projections 29 have the same height. In addition, the projections 29 are positioned on both sides of the support body 1 above each other.

In the embodiment according to FIG. 19, the sealing body 3 has at both sides of the support body 1 annular projections 29 which have the same height. The projections 29 on both sides 7, 8 of the support body 1 are adjacently positioned at a distance from each other so that the basic configuration of the sealing body 3 corresponds to the embodiments according to FIGS. 16 and 17.

The projections 29 at the outer side 8 are displaced in relation to the projections 29 at the outer side 7 so that, viewed in a plan view of the support body 1, the projections 29 are not positioned above each other but are displaced relative to each other in the width direction of the support body part 1a.

As shown in FIG. 20, the annular projections which are positioned at a distance from each other at both sides 7, 8 of the support body 1 can also be positioned at the same level so that, viewed in plan view, they are arranged above each other.

While in the embodiments according to FIGS. 16 to 20 the support body 1 is partially covered at both sides 7, 8 of its outer support body part 1a with the sealing body 3 with its projections 29, 30, respectively, FIG. 21 shows an example where the annular projection 29 is arranged only at one side 7 of the support body 1. The sealing body 3 surrounds the outer rim 12 of the support body 1 and extends to the outer side 8 of the support body 1.

The sealing body 3 is provided with a depression 31 in the region adjacent to the projection 29. It extends to both sides of the projection 29 across its length. The depression 31 serves to accommodate the material that is displaced as a result of the elastic deformation of the projection 29 upon compression of the sealing body 3 between the housing parts 4, 5.

FIGS. 22, 22a, and 22b show in an exemplary fashion a sealing body 3 whose projections 29 in their length direction have different height. The support body part 1c is provided with openings 32 distributed across its length through which the screws and the like can be pushed with which the two housing parts 4, 5 with intermediate positioning of the seal can be connected to each other by screwing. In the region between the openings 32, the projections 29 have a greater height (FIG. 22a) than in the region of the openings 32 (FIG. 22b). Thus, the height of the projections 29 can increase steadily away from the region of the openings 32 so that the projections 29 at half the length between the regions of the openings 32 have their greatest height. With such a configuration, the sealing action of the sealing body 3 is improved. Moreover, bending of the housing parts 4, 5 by the screwing action is compensated and a good sealing action is achieved.

The projections 29, 30 of the sealing body 3 can have different profile shapes in the described embodiments. Also, the distance between the neighboring projections 29, 30 can be designed variably in order to adapt the seal to different application situations.

FIG. 23 shows a seal whose support body 1 is angled at the outer rim. In this way, a conical support body part 1d is formed which comprises the sealing body 3. With such a seal, housing parts 4, 5 whose cast surfaces have not been machined can be sealed properly. The housing part 4 is provided, for example, at its sealing surface in the rim region with a widened portion 33 which can be reliably sealed by the sealing body 3.

With the seal, settling movements of the housing parts 4, 5 and of the screw connection itself can be counteracted.

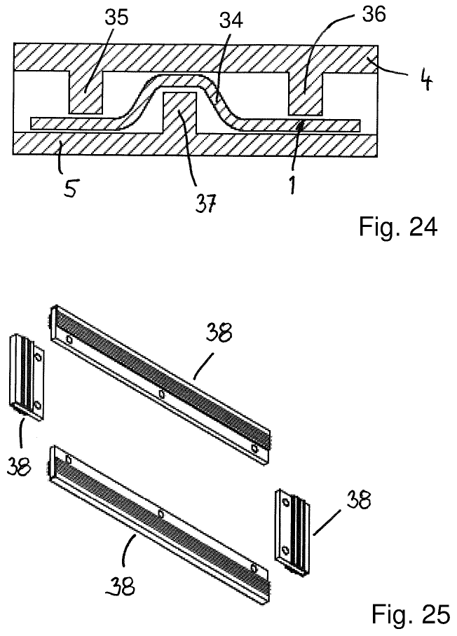

FIG. 24 shows a further possible configuration of the support body 1. It comprises a corrugated elevation 34 which is elastically deformed upon screwing together the two housing parts 4, 5.

The housing part 4 comprises strip-shaped projections 35, 36 arranged at both sides of the elevation 34 which, when joining the housing parts 4, 5, are pressing onto the planar part of the support body 1 in the region adjacent to the elevation 34.

The other housing part 5 comprises a strip-shaped projection 37 which upon joining of the housing parts 4, 5 projects into the elevation 34.

The corrugated elevation 34 of the support body as well as the projections 35 to 37 of the housing parts 4, 5 are matched to each other such that the elevation 34 is elastically deformed upon joining the housing parts 4, 5. The projections 35, 36 of the housing part 4 serve as a hold-down device with which the support body 1 in the region adjacent to the elevation 34 is pushed against the housing part 5.

As a result of the elastic deformation of the elevation 34, the housing parts 4, 5 are properly electrically conductively connected to each other by means of the support body 1.

The described seals are of an annular configuration. The annular shape is however not mandatory and is less suitable, for example, for sealing elongate components, such as battery housings of motor vehicles. In these cases, the seal is designed as a sealing strip 38 (FIG. 25) wherein, in case of an angular configuration of the sealing surface, the correspondingly strip-shaped seals 38 are joined to a rectangular sealing ring. In this context, the sealing strips 38 are contacting each other miter-like. At the butt joint, sealing between adjacent sealing strips 38 is then realized, for example, with liquid silicone.

Such sealing strips 38 also have the described support body which is clamped between the two housing parts 4, 5 to be sealed relative to each other and which is thereby elastically deformed. The sealing body 3 is fastened to the support body and can have a configuration in accordance with the afore described configurations.

Upon compression of the support body 1 between the two housing parts 4, 5, the support body 1 is compressed in the described way to the sealing height such that the sealing gap height is reached and the support body is contacting seal-tightly and electrically conductively both facing sides of the housing parts 4, 5 in a circumferentially closed configuration. The support body 1 can have in the described manner corresponding profilings which are designed in an advantageous manner such that they can penetrate an oxide layer, as it occurs in housing parts 4, 5 comprised of aluminum, so that the housing parts 4, 5 are connected electrically conductively to each other despite the oxide layer.

For improving the conductivity and for reducing corrosion, the support body can comprise corresponding coatings which can be employed in case of all embodiments of the support body.

The seals are distinguished in that they fulfill two functions, namely prevent the penetration of dirt particles, water and the like between the housing parts 4, 5 from the exterior and provide at the same time the required EMC compatibility. The sealing body 3 is advantageously designed such that it can fulfill also the IP requirement of code 9K. Due to the elastic deformation of the electrically conductive support body 1, an optimal EMC effect is provided. Since for both functions only a single component is required, an inexpensive and very effective sealing action and shielding action are provided. The seal can be clamped circumferentially in a detachable and vibration-safe way between the two housing parts 4, 5 which are advantageously diecast housings. The gap between the housing parts 4, 5 is reliably sealed against penetration from the exterior. At the same time, the seal shields the housing which is combined of the housing parts 4, 5 against emission of electrical disturbance sources.

In the described embodiments, the shielding action by means of the electrically conductive support body 1 is independent from the minimum contact pressure required for the sealing body 3.

The thickness 13 of the support body 1 is smaller than the sealing gap height between the two housing parts 4, 5. In this way, it is ensured that the sealing body 3, when joining the housing parts 4, 5 to the housing, is elastically deformed in any case and can thus exert its sealing action.

The sealing body 3 seals the housing with respect to dust, against moisture or even saltwater. In particular, the seal or the sealing body 3 ensures a seal-tightness in case of a steam cleaner of up to 100 bar. The seal also enables the vehicle to drive through water so that in such cases no water can penetrate through the gap between the housing parts 4, 5 into the housing. This is in particular an important advantage when the housing is a battery housing of a vehicle. The sealing body 3 is also stable in regard to change of climate and stable in regard to salt spray.

With the support body 1, a shielding action against disturbance currents or disturbance radiation is provided. Also, an electrostatic charging of the housing is prevented. In order to be able to control the pretension force due to the elastic deformation of the support body 1, it can be advantageously perforated. The perforation is then provided such that the desired pretension force is achieved.

The specification incorporates by reference the entire disclosure of prior filed German application for patent No. 10 2020 000 632.9 having a filing date of Jan. 28, 2020.

While specific embodiments of the invention have been shown and described in detail to illustrate the inventive principles, it will be understood that the invention may be embodied otherwise without departing from such principles.

What is claimed is:

1. A seal comprising:
at least one support body;
at least one sealing body disposed in a sealing body region of the at least one support body;
wherein the at least one support body comprises a projecting region that projects past the at least one sealing body;
wherein the at least one support body is electrically conductive at least in the projecting region.

2. The seal according to claim 1, wherein the projecting region of the at least one support body is elastically deformable.

3. The seal according to claim 1, wherein the at least one support body is comprised entirely of electrically conductive material.

4. The seal according to claim 1, wherein the at least one support body is comprised of electrically nonconductive material and further comprised of an electrically conductive coating applied to the electrically nonconductive material at least in the projecting region of the at least one support body.

5. The seal according to claim 1, wherein the at least one support body is formed of a metal sheet.

6. The seal according to claim 1, wherein at least the projecting region of the at least one support body is embodied as a shaped part.

7. The seal according to claim 1, wherein the projecting region of the at least one support body is arranged displaced in a direction transverse to a plane of the at least one support body in relation to the sealing body region.

8. The seal according to claim 1, wherein the projecting region of the at least one support body comprises a rib-shaped structure.

9. The seal according to claim 1, wherein the projecting region of the at least one support body comprises a profiling extending in a direction transverse to a longitudinal direction of the at least one support body.

10. The seal according to claim 9, wherein the profiling is formed by profile parts positioned one after the other in a circumferential direction of the at least one support body.

11. The seal according to claim 10, wherein the profile parts have a corrugated configuration.

12. The seal according to claim 1, wherein the projecting region of the at least one support body comprises a profiling extending in a longitudinal direction of the at least one support body.

13. The seal according to claim 12, wherein the profiling is a corrugated structure, viewed in cross section, and extends in a longitudinal direction of the at least one support body.

14. The seal according to claim 1, wherein the at least one support body comprises form fit means.

15. The seal according to claim 14, wherein the form fit means extend transversely to the at least one support body.

16. The seal according to claim 14, wherein the form fit means are transversely projecting tabs.

17. The seal according to claim 1, wherein the projecting region comprises at least one projecting pin.

18. The seal according to claim 1, wherein the at least one sealing body comprises a profiling at least at one side of the at least one support body.

19. The seal according to claim 1, wherein a thickness of the at least one support body is smaller than a height of a sealing gap to be sealed.
